(19) United States
(12) Patent Application Publication
(10) Pub. No.: US 2019/0146091 A1
(43) Pub. Date: May 16, 2019

(54) UNDERWATER LIDAR

(71) Applicant: OEWAVES, INC., PASADENA, CA (US)

(72) Inventors: Andrey B. MATSKO, Pasadena, CA (US); Anatoliy A. SAVCHENKO, Glandale, CA (US); Prathamesh S. DONVALKAR, Portland, OR (US)

(21) Appl. No.: 16/152,332

(22) Filed: Oct. 4, 2018

Related U.S. Application Data
(60) Provisional application No. 62/587,394, filed on Nov. 16, 2017.

(51) Int. Cl. G01S 17/89; G01S 7/48; H01S 3/094; H01S 5/14

(52) U.S. Cl. CPC G01S 17/89; H01S 5/141; H01S 3/094069; G01S 7/4808

(57) ABSTRACT

The disclosure relates in some aspects to Light Detection and Ranging (LIDAR) for underwater applications. An exemplary LIDAR system described herein uses a green and/or blue semiconductor laser, which is self-injection locked using a high-quality factor micro-resonator, such as a whispering gallery mode (WGM) resonator. The self-injection locking results in a single mode operation of the laser and reduction of its linewidth. The self-injection allows transferring frequency modulation from the optical micro-resonator to the laser frequency without significant impact on the power of the laser. In some examples, the LIDAR operates in a continuous wave frequency modulated (CWFM) mode. The CWFM LIDAR may be used for ranging, velocity determination, etc., particularly for underwater applications and may be mounted to watercraft or to aircraft designed to fly over water to take underwater measurements.

### PRIORITY CLAIM AND CROSS-REFERENCE TO RELATED APPLICATION

This patent document claims the priority of U.S. Provisional Application No. 62/587,394 entitled “Underwater LIDAR,” filed on Nov. 16, 2017, the entire disclosure of which is incorporated by reference herein.

### FIELD OF THE DISCLOSURE

Various aspects of the present disclosure relate to Light Detection and Ranging (LIDAR). More specifically, aspects of the disclosure relate to systems, methods and apparatus for underwater LIDAR using a self-injection locked semiconductor laser.

### BACKGROUND

There is an increasing demand for underwater ranging and communications for such applications as sea floor tracking and offshore oil exploration. Unmanned underwater vehicles and autonomous underwater vehicles may also benefit from low power ranging and communications systems. Acoustic systems are often utilized for underwater applications because of the low attenuation of the sound waves. However, the bandwidth of acoustic channels can be limited and the resolution of ranging may be low. Moreover, the relatively slow speed of sound can result in significant delays. Techniques that instead utilize radio or microwave frequencies may be significantly attenuated by water, and the same is generally true for the majority of the optical wavelengths. Accordingly, it would be desirable to address these and other issues so as to provide, among other features, useful methods and apparatus for underwater LIDAR.

### SUMMARY

This document provides, among other features, techniques and devices that use optical micro-resonators to provide single mode injection locking of light from a multimode laser light source for underwater LIDAR or other applications.

In one aspect, an apparatus includes: a multimode laser light source configured to transmit light having a blue and/or green color wavelength; an optical resonator optically coupled to the laser light source and configured to provide single mode injection self-locking of the laser light source; and an optical port coupled to the micro-resonator and configured to emit a single mode monochromatic laser beam.

In another aspect, method includes: generating multimode laser light having a blue and/or green color wavelength using a multimode laser light source; optically coupling the laser light to an optical resonator configured so a propagating wave circulates within the resonator; optically coupling a portion of the propagating wave out of the resonator; and applying at least some of the portion of the propagating wave coupled out of the resonator to the laser light source to provide single mode self-injection locking of the laser light source to generate a single mode injection monochromatic locked laser beam.

In yet another aspect, an apparatus includes: an optical resonator; means for generating multimode laser light having a blue and/or green color wavelength using a multimode laser light source; means for optically coupling the laser light to the optical resonator to cause a propagating wave to circulate within the resonator; and means for optically coupling a portion of the propagating wave out of the resonator and for applying at least some of the portion of the propagating wave coupled out of the resonator to the laser light source to provide single mode self-injection locking of the laser light source to generate a single mode injection locked monochromatic laser beam.

### BRIEF DESCRIPTION OF THE DRAWINGS

FIG. 1 shows an example of a LIDAR system having a high-Q micro-resonator configured to provide single mode injection locking of multimode laser light.

FIG. 2 shows an example of a LIDAR system wherein the high-Q micro-resonator is a whispering gallery mode (WGM) resonator.

FIG. 3 shows another example of a LIDAR system having a high-Q micro-resonator configured to provide single mode injection locking of multimode laser light.

FIG. 4 is a schematic block diagram of an exemplary controller for controlling a LIDAR system having a high-Q WGM resonator.

FIG. 5 is a schematic block diagram of an exemplary data analysis device for analyzing data from a LIDAR system having a high-Q WGM resonator.

FIG. 6 illustrates an exemplary modification of a laser spectrum due to self-injection locking where one curve is the spectrum of the self-injection locked laser and the other curve is the spectrum of the free running laser.

FIG. 7 illustrates an exemplary effect of injection locking of a laser diode to a WGM, where the output power drops when the laser locks to a WGM.

FIG. 8 illustrates an exemplary high order WGM emitting in two directions.

FIG. 9 illustrates exemplary normalized power over time.

FIG. 10 is a block diagram summarizing features of a system having a WGM resonator configured for single mode injection locking of multimode laser light.

FIG. 11 is a block diagram summarizing further features of a system having a WGM resonator configured for single mode injection locking of multimode laser light.

FIG. 12 is a flow diagram of an exemplary method according to aspects of the present disclosure.

FIG. 13 illustrates an exemplary application of a LIDAR system using blue and/or green color wavelengths for underwater ranging.

FIG. 14 illustrates another exemplary application of a LIDAR system using blue and/or green color wavelengths for seafloor mapping.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. In the figures, elements may each have a same reference number or a different reference number to suggest that the elements represented could be different and/or similar. However, an element may be flexible enough to have different implementations and work with some or all of the systems shown or described herein. The various elements shown in the figures may be the same or different and, which one is referred to as a first element and which is called a second element is arbitrary.

### Overview

As noted above, underwater ranging and communications techniques that attempt to utilize radio and microwave frequencies may be significantly attenuated by water, and the same is generally true for most optical wavelengths, rendering conventional LIDAR generally poor or ineffective for underwater applications. However, blue, green, and blue-green light wavelengths are not attenuated in water as much. As used herein, the terms “blue and/or green color light” and “green and/or blue color light” refer to electromagnetic radiation having a wavelength between 350 nm and 570 nm and include blue-green light. The absorption coefficient of water is about 2×10⁻³ to 10⁻² per meter at around 450 nm wavelength, so that an optical LIDAR operating within these wavelengths is feasible. One issue in designing a high-resolution LIDAR using such wavelengths is that the system should have a frequency-modulatable coherent light source with adequate spectral purity and frequency stability.

Herein, a miniature power efficient underwater LIDAR system is provided according to one aspect of the disclosure that is based on an agile tunable blue diode laser characterized with both high spectral purity and high frequency stability.

Exemplary LIDAR systems described herein may be based on a green and/or blue semiconductor laser self-injection locked using a high-quality factor micro-resonator. Self-injection locking is an efficient technique for locking a laser to an optical ring resonator. Self-injection locking does not depend on the resonator morphology and is efficient for most any ring cavity provided there is sufficient optical feedback to the laser (as well as high quality factor of the cavity). One non-limiting, non-exclusive example of a suitable optical micro-resonator is a monolithic resonator such as a whispering gallery mode (WGM) resonator. The self-injection locking results in a single mode operation of the laser and reduction of its linewidth. The self-injection allows transferring frequency modulation from the optical micro-resonator to the laser frequency without significant impact on the power of the laser. For example, the LIDAR can operate in a continuous wave frequency modulated (CWFM) mode.

Note that the self-injection locking results in transformation of multi-mode lasing into a single mode operation of the LIDAR device for any wavelength of the laser operation. Self-injection locking results from a resonant optical feedback from the optical resonator. Note also that all of the modes of the micro-resonator, as well as the optical path between the resonator and the laser, introduce different phase shifts to the optical feedback. As a result, only one laser mode receives a favorable generation condition. This effect can be enhanced by forming a resonator to have a free spectral range dissimilar with from free spectral range of the laser cavity.

In particular, an exemplary LIDAR system is described herein that includes high-Q factor micro-resonators that may be comprised or composed of MgF₂ and CaF₂ and characterized by Q factors exceeding 10⁹ at around 450 nm wavelengths.

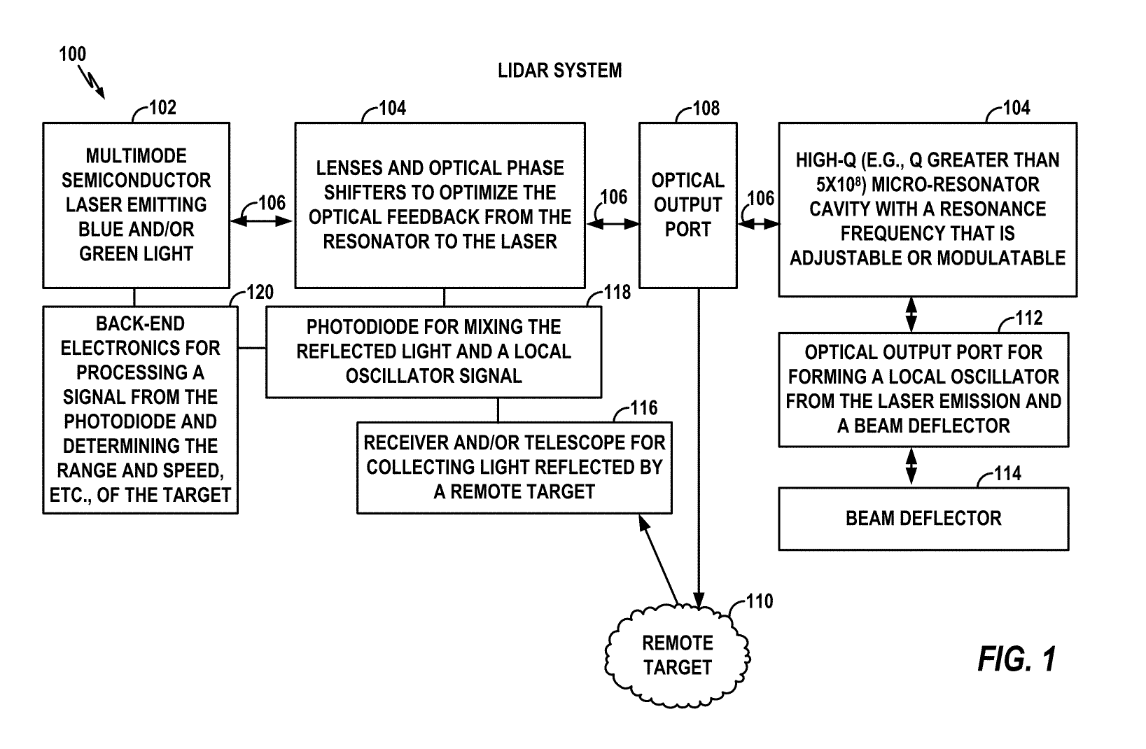

FIG. 1 provides a broad overview of an exemplary LIDAR system 100. The system 100 includes a multimode semiconductor laser 102 that emits blue and/or green light and a high-Q micro-resonator 104 (with, e.g., a Q greater than 5×10⁸) with a resonance frequency that is adjustable or modulatable (e.g. a resonator capable of adjusting its resonance frequency and/or modulating its resonance frequency). An optical path 106 is provided between the laser 102 and a cavity of the resonator 104 (via various components interposed along the optical path).

A first optical output port 108 is provided for coupling a portion of light emitted by the laser 102 into the resonator 104 and emitting another portion of the laser light to a remote target 110. A second optical output port 112 is provided for forming a local oscillator from the laser emission and a beam deflector 114. A receiver and/or telescope 116 collects light reflected by the remote target 110. A photodiode 118 mixes the reflected light and a local oscillator signal (e.g. a signal reflected from the beam deflector 114 and fed back through the resonator 104 to the laser 102). A back-end electronics component 120 processes the signal from the photodiode 118 to determine the range and speed, etc., of the remote target 110. The optical path 106 supports light propagation and coupling from the laser 102 to the resonator 104 and from the resonator 104 to the laser 102. The optical path may include lenses and optical phase shifters 122 to optimize the optical feedback from the resonator 104 to the laser 102.

A major technical difference of the system of FIG. 1 from earlier LIDAR systems is that the system of FIG. 1 employs a laser that emits multimode light when not self-injection locked. Self-injection locking results in transformation of a multimode laser to a single-mode operating laser. Note that a self-injection locked laser is not an external cavity laser, since the lasing occurs without the resonance cavity providing the optical feedback. In many of the examples described herein, the frequency modulation is enforced by the micro-resonator.

### Exemplary Embodiments

In some aspects of the disclosure, a suitable laser light source for a LIDAR system is provided by optically coupling a laser light source to an optical resonator using, for example, a prism. In other examples, other evanescent field couplers may be used, such as an optical fiber, optical fiber taper, or optical grating. The optical resonator may be dimensioned and constructed of materials that support a WGM at a wavelength emitted by the source laser, and may be constructed of materials (for example electro-optical materials) that permit controlled modulation of an optical property (e.g. refractive index) of the optical resonator. Modulation of the optical property of the WGM resonator (for example, by application of an electrical potential, change of temperature, and/or mechanical pressure) alters the frequency of the WGM.

Light may be coupled from a CWFM laser source (e.g., a multimode, blue and/or green laser source) into the WGM resonator by evanescent wave coupling, for example using a prism, an optical fiber with a faceted face, or a similar device. Similarly, light from a counter-propagating WGM wave within the optical resonator may be coupled out and returned to the source laser to provide optical injection locking, which in turn provides a narrow linewidth laser output. Modulation of the optical property of the WGM optical resonator (for example, via electrodes, a resistive heater, and/or a piezoelectric device) alters the frequency supported by the WGM. This in turn alters the frequency utilized for optical injection locking and results in modulating the frequency output of the laser, which continues to have a very narrow linewidth. With this arrangement, controlled modulation of the optical properties of the WGM resonator in optical communication with the multimode blue and/or green CWFM laser permits direct generation of highly linear (or highly consistently nonlinear) frequency chirps through optical components (for example, by a chirp generator programmed to produce one or more chirp patterns and intervals).

The high degree of reproducibility and narrow linewidth of the resulting laser emissions permits the use of a simple beam splitter (or similar device) to provide a LIDAR system where the modulated CWFM laser (serving as the source of an emitted chirp used to characterize a reflecting object) also serves as the source of the reference chirp used to characterize the returning reflected chirp. Highly reproducible frequency chirps may be produced by altering the optical properties of the optical resonator in a controlled manner, for example by applying electrical current to the optical resonator, applying pressure to the optical resonator, and/or altering the temperature of the optical resonator. A variety of configurations is suitable for optically coupling a laser source and a WGM resonator.

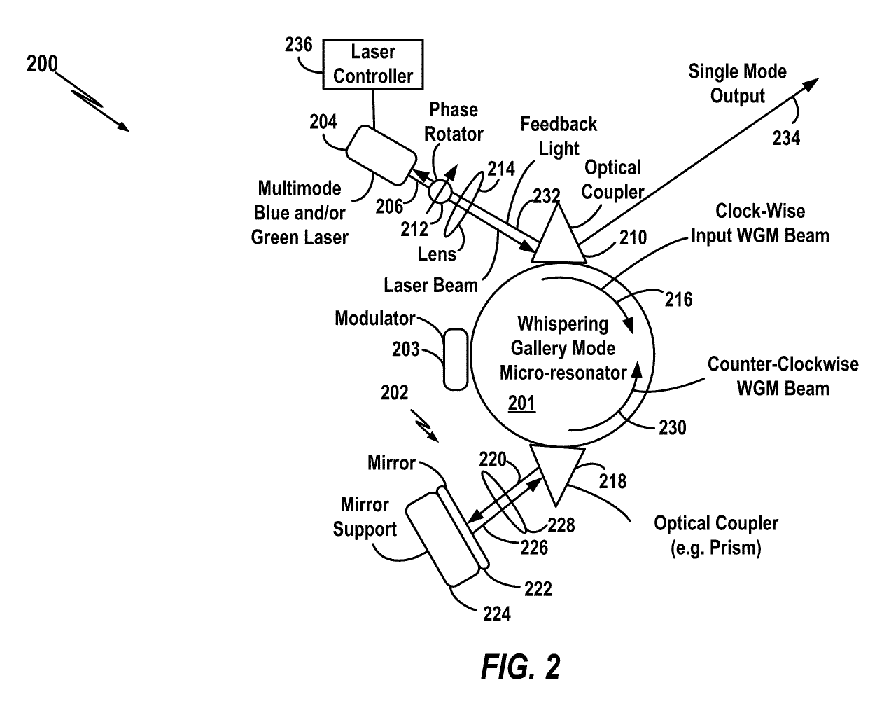

FIG. 2 illustrates an exemplary system or apparatus 200 having a WGM micro-resonator 201 along with a set of feedback optics 202 and a modulator (modulation component) and/or transducer (transducer component) 203, such as a pressure actuator or resistive heater. A multimode source laser 204 provides a laser beam 206 having a blue and/or green color wavelength that is coupled into a WGM resonator 201 using a first optical coupler 210, which may be a prism and which may serve as a transmit component. According to one aspect, the laser 204 outputs a wavelength of between 350 nm to 570 nm. According to another aspect, the laser 204 outputs a wavelength of between 380 nm to 450 nm. According to another aspect, the laser 204 outputs a wavelength of between 400 nm to 460 nm. According to yet another aspect, the laser 204 outputs a wavelength of about 480 nm. According to another aspect, the laser 204 outputs a wavelength of about 418 nm.

In the example of FIG. 2, the laser beam 206 is passed through a phase rotator 212 and directed into the first optical coupler 210 using a first lens 214. A subset of the frequencies represented in the laser beam 206 propagates in a first direction as a self-reinforcing WGM mode wave 216 (herein, a first propagating wave) through the resonator that is “captured” in the WGM. A portion of the propagated light is coupled out of the WGM resonator 201 by a second optical coupler (e.g. prism) 218, and an output light beam 220 is reflected by a mirror 222 (which can be supported by a mount 224) to provide a reflected light beam 226. The output light beam 220 and/or the reflected light beam 226 are directed with a lens 228.

The reflected light beam 226 is coupled back into the WGM resonator 201 to form a counter-propagating wave 230 (herein a second propagating wave, i.e. a wave propagating in a second direction opposite to the first direction), which is coupled out of the resonator 201 by the first optical coupler 210 and returned to the source laser 204 as feedback light 232, where optical injection results in a narrowed linewidth laser output 234 via coupler 210. Notably, and as discussed above, the feedback light 232 causes the laser output 234 to have a single mode due to self-injection locking of the micro-resonator 208. In implementations where the optical coupler 210 is a prism, the narrowed linewidth output 234 of the source laser 204 can be output through an exposed facet of the prism and utilized for LIDAR. Thus, a multimode laser 204 may be used to output a single mode laser beam 234 in the blue and/or green spectrum (for example at about 480 nm). As shown, the laser 204 may be under the control of a laser controller 236. In some examples, the linewidth of the laser is 1 MHz, 10 kHz, or 100 Hz.

In other aspects of the present disclosure, optical coupling between a source laser and an optical resonator and between the optical resonator and a reflector to provide a counter-propagating wave may be achieved using a waveguide. Suitable waveguides include optical fibers and optically conductive materials provided on silicon wafers. In other aspects, optical filters can be incorporated. For example, an optical spatial filter (e.g., a pinhole) may be placed between a second optical coupler (such as the coupler 218) and a reflector (such as the mirror 222) of the feedback optics.

While the example of FIG. 2 uses a reflector to provide a counter-propagating wave within the WGM resonator, other embodiments do not use a mirror or reflector. For example, in some embodiments, light scattering within the material of the WGM resonator provides a counter-propagating wave of sufficient intensity to be sufficient for optical injection locking of the source laser. In other embodiments, features can be introduced into and/or on the surface of a WGM resonator to provide a counter-propagating wave. Suitable features include inclusions within the body of the WGM resonator, pits, channels, or other features generated on the surface of the WGM resonator, and/or an optical grating generated on the surface of the WGM resonator. The modulator 203 may be used to alter the propagation characteristics of the WGM.

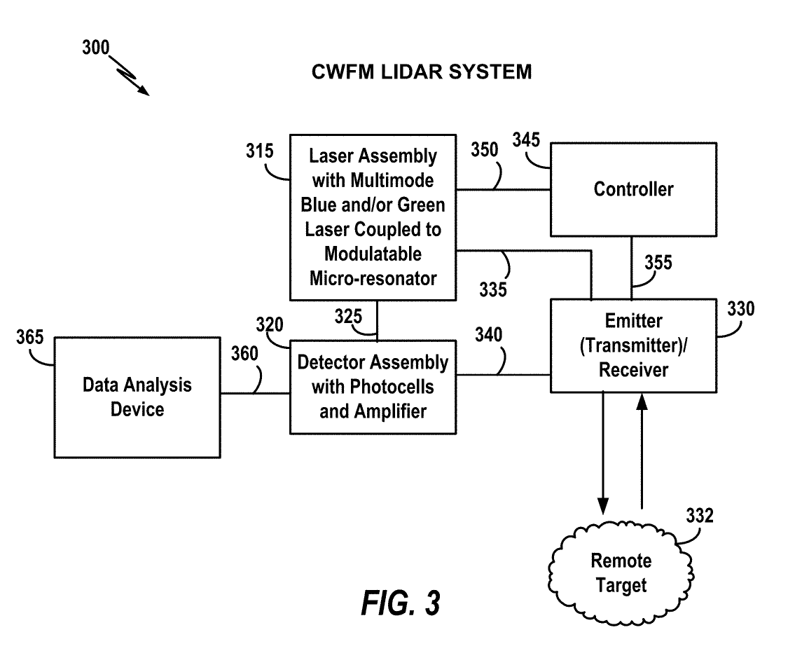

FIG. 3 provides a schematic depiction of a CWFM LIDAR system 300 according to one aspect of the present disclosure. The CWFM LIDAR 300 may be used for ranging, velocity determination, etc., particularly for underwater applications and may be mounted onto watercraft or aircraft designed to fly over water and take underwater measurements. As shown in FIG. 3, the exemplary LIDAR system 300 includes a laser assembly 315 that includes a multimode blue and/or green laser source that is optically coupled to a modulatable micro-resonator (e.g., a WGM resonator) to provide a narrow linewidth laser output. Due to the micro-resonator, the output of the laser assembly 315 may ultimately be a single mode having a wavelength that is transparent or nearly transparent to fresh water or seawater. The LIDAR system 300 may also include a detector assembly 320 that includes, in some examples, at least two photocells and an amplifier that serves to integrate the outputs from the photocells in the form of electronic data. An optical transfer device 325 (e.g., a waveguide) provides optical communication between the laser assembly 315 and the detector assembly 320.

The laser assembly 315 may also be in optical communication 335 with an emitter/receiver 330 that includes an emitter (or transmit component) that transmits an optical chirp generated by the laser assembly 315 into the environment, such as to a remote object 332, and a receiver (or receive component) that receives reflected chirps. The emitter/receiver 330 is similarly in optical communication 340 with the detector assembly 320. A controller 345 provides control functions to the laser assembly 315 and/or the emitter/receiver subassembly 330. For example, electronic communication 350 between the controller subsystem 345 and the laser assembly 315 can provide modulation of the WGM optical resonator (for example, via a resistive heater, one or more piezoelectric actuator(s), and/or one or more electrical contact(s)) to generate an optical chirp. Such a controller subsystem can also be in electronic communication 355 with the emitter/receiver 330 via 355 in order to provide control over operations related to direction and/or scanning of the emitted chirp. The controller 345 can also control the functions of additional components, not shown, such as one or more optical switches that are integrated into lines of optical communication.

Electronic data provided by the detector assembly 320 may also be provided with electronic communication 360 with a data analysis device 365. The data analysis device 365 can include one or more processing circuits. For example, the data analysis device 365 can include a fast Fourier transform module for initial processing of combined data from reflected chirps received from the environment and a reference, non-reflected chirp. The transformed data from such a fast Fourier transform module may then be provided to processing circuits of the data analysis device 365 for derivation of spatial coordinates and/or velocity of a reflective surface that provided the reflected chirp. The processing circuits can also derive secondary information regarding properties of the reflective surface (for example, color, composition, texture, etc.). The data analysis device 365 can also store and/or transmit such data derived from one or more reflected chirps in the form of a point cloud (i.e. a collection of data points representing spatial coordinates of reflecting surfaces). Such a point cloud can also encode information related to velocity and/or secondary information.

In some aspects, the LIDAR systems described herein may be used for underwater ranging and may be integrated into watercraft or aircraft that fly over water. In such aspects, the LIDAR can provide spatial data related to position and/or velocity of reflecting objects within the scanning range of the LIDAR system, or other characteristics such as size, shape, relative speed, etc. The scanning range may be a plane and/or a volume, depending upon the configuration of the LIDAR system. Such data can be represented as a point cloud, wherein each point represents at least 2D or 3D spatial coordinates related to a reflecting object. In some embodiments, characteristics of a reflected chirp (for example, amplitude and/or intensity) provide information related to additional characteristics of the reflecting object (for example, composition, color, surface texture, etc.). Values for such additional characteristics can be encoded in the points of the point cloud.

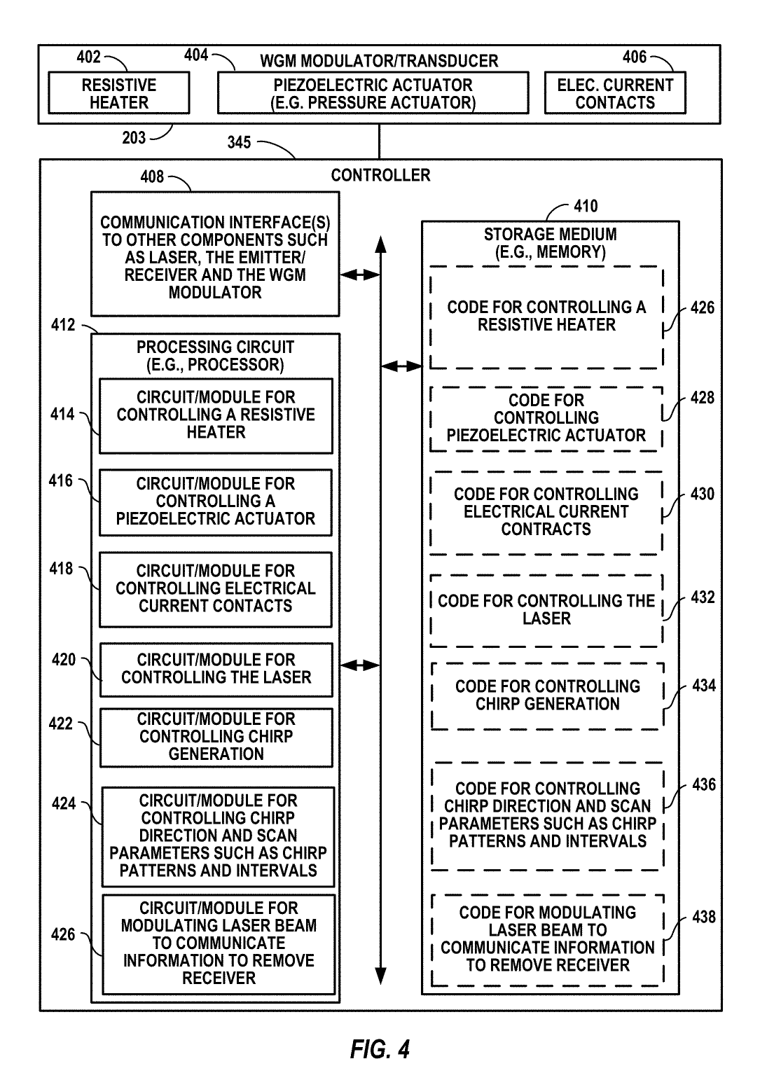

FIG. 4 illustrates features of an exemplary controller 345, such as the controller of FIG. 3, and an exemplary WGM modulator or transducer 203, such as the modulator of FIG. 2. As shown, the WGM modulator 203 of FIG. 4 may include one or more of: a resistive heater 402; a piezoelectric actuator (such as a pressure actuator) 404; and a set of electric current contacts 406, the choice of which may depend on the particular characteristics of the WGM cavity to be modulated.

The controller 345 of FIG. 4 includes: one or more communication interfaces 408 for communicating with the other components of a LIDAR system such as a laser, an emitter/receiver, and the modulator 203; a storage medium 410 for storing data or other information; and a processing circuit 412 (e.g., at least one processor, processing component, and/or other suitable circuitry). These components may communicate with one another via signaling busses or the like, represented by the connection lines in FIG. 4. Note that other components, such as clocks, peripherals, voltage regulators, and power management circuits, may also be employed, though not shown.

The storage medium 410 may be, for example, a computer-readable, machine-readable, and/or processor-readable device for storing programming, such as processor-executable code or instructions (e.g., software or firmware), electronic data, databases, or other digital information. The storage medium 410 may also be used for storing data used by the processing circuit 412 when executing programming. The storage medium 410 may be any available media accessible by a general purpose or special purpose processor, including portable or fixed storage devices, optical storage devices, and various other mediums capable of storing, containing or carrying programming. The storage medium 410 may include, e.g., a magnetic storage device (e.g., hard disk, floppy disk, magnetic strip), an optical disk (e.g., a compact disc (CD)), a smart card, a flash memory device, a random access memory (RAM), read only memory (ROM), programmable ROM (PROM), electrically programmable ROM (EPROM), etc., or any other suitable medium for storing software and/or instructions. The storage medium 410 may be embodied in an article of manufacture (e.g., a computer program product). The computer program product may include a computer-readable medium in packaging materials. In some implementations, the storage medium 410 is a non-transitory (e.g., tangible) storage medium. For example, the storage medium 410 may be a non-transitory computer-readable medium storing computer-executable code, including code to perform various operations as described herein. Programming stored by the storage medium 410, when executed by the processing circuit 412, causes the processing circuit 412 to perform one or more of the various functions and/or process operations described herein.

The processing circuit 412 may be generally adapted or configured for executing programming stored on the storage medium 410. As used herein, the terms “code” or “programming” include instructions, instruction sets, data, code, code segments, program code, programs, programming, subprograms, software modules, applications, software applications, software packages, routines, subroutines, objects, executables, threads of execution, procedures, functions, etc., whether referred to as software, firmware, microcode, hardware description language, or otherwise.

The processing circuit 412 may include circuitry configured to implement desired programming provided by appropriate media. For example, the processing circuit 412 may be implemented as one or more processors, one or more controllers, and/or other structure configured to execute executable programming. Examples of the processing circuit 412 may include a general-purpose processor, a digital signal processor (DSP), an application-specific integrated circuit (ASIC), or other programmable logic component, etc., or any combination thereof designed to perform the functions described herein. A general-purpose processor may include a microprocessor, as well as any conventional processor, controller, microcontroller, or state machine. The processing circuit 412 may be implemented as a combination of computing components, such as a controller and a microprocessor, or other varying configurations. These examples are for illustration and other suitable configurations within the scope of the disclosure are also contemplated. The processing circuit 412 may be adapted to control or perform any or all of the features, processes, functions, operations and/or routines for any or all of the apparatuses or devices described herein. As used herein, the term “configured” in relation to the processing circuit 412 may refer to the processing circuit 412 being one or more of adapted, employed, implemented, and/or programmed to perform a particular process, function, operation and/or routine according to various features described herein.

In at least one example, the processing circuit 412 includes one or more of: a circuit/module 414 for controlling the resistive heater 402 to modulate a WGM resonator; a circuit/module 416 for controlling piezoelectric actuator 404 to modulate a WGM resonator; a circuit/module 418 for controlling the electrical current contacts 406 to modulate a WGM resonator; a circuit/module 420 for controlling a laser of a LIDAR system such as laser 102 of FIG. 1; a circuit/module 422 for controlling chirp generation, which may involve controlling the WGM modulator 203 of FIG. 2 to cause a chirp to be generated; a circuit/module 424 for controlling chirp direction and scan parameters such as chirp patterns and intervals, which may involve controlling the emitter 330 of FIG. 3 to control the direction a chirp is transmitted and the angle of its beam; and a circuit/module 426 for modulating the laser beam to communicate information to remote receiver or other remote device. Note that, in some examples, the circuit/module 422 for controlling chirp generation operates to controllably chirp the monochromatic laser beam via a signal applied to the resonator.

As noted, a program stored by the storage medium 410, when executed by the processing circuit 412, may cause the processing circuit 412 to perform one or more of the various functions and/or process operations described herein. For example, the program may cause the processing circuit 412 to perform the various functions, steps, and/or processes described herein with respect to the various figures discussed herein. As shown in FIG. 4, the storage medium 410 may include one or more of: code 427 for controlling a resistive heater to modulate a WGM resonator; code 428 for controlling piezoelectric actuator to modulate a WGM resonator; code 430 for controlling electrical current contacts to modulate a WGM resonator; code 432 for controlling the laser of a LIDAR system; code 434 for controlling chirp generation; code 436 for controlling chirp direction and scan parameters such as chirp patterns and intervals; and code 438 for modulating the laser beam to communicate information to remote receiver.

In at least some examples, means may be provided for performing the functions illustrated in FIG. 4 and/or other functions illustrated or described herein. For example, the means may include one or more of: means, such as circuit/module 414, for controlling a resistive heater to modulate a WGM resonator; means, such as circuit/module 416, for controlling piezoelectric actuator to modulate a WGM resonator; means, such as circuit/module 418, for controlling electrical current contacts to modulate a WGM resonator; means, such as circuit/module 420, for controlling the laser of a LIDAR system; means, such as circuit/module 422, for controlling chirp generation; means, such as circuit/module 424, for controlling chirp direction and scan parameters such as chirp patterns and intervals; and means, such as circuit/module 426, for modulating the laser beam to communicate information to remote receiver.

Alternatively, the means may include one or more of: means, such as laser 204 of FIG. 2, for generating multimode laser light having a blue and/or green color wavelength using a multimode laser light source; means, such as optical port 210, for optically coupling the laser light to a WGM resonator configured to cause a propagating wave to circulate within the WGM resonator; and means, such optical coupler 210 and lens 214, as for optically coupling a portion of the propagating wave out of the WGM resonator and for applying at least some of the portion of the propagating wave coupled out of the WGM resonator to the laser light source to provide single mode injection locking of the laser light source to generate a single mode injection locked laser beam.

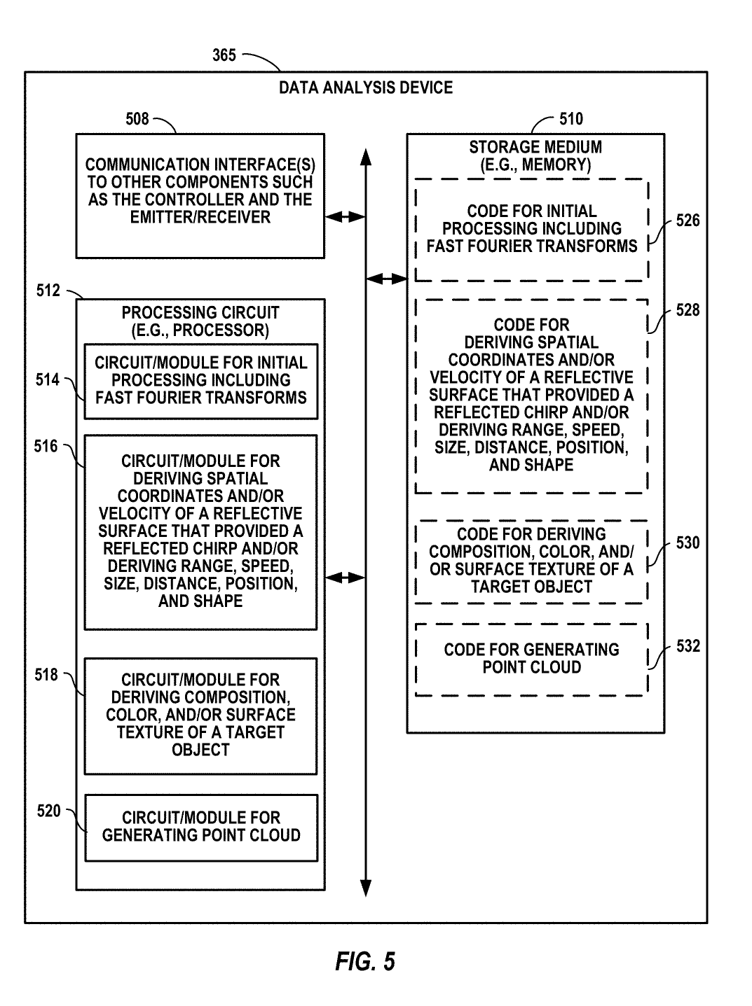

FIG. 5 illustrates features of an exemplary data analysis device 365, such as the device of FIG. 3. The controller 365 of FIG. 5 includes: one or more communication interfaces 508 for communicating with the other components of a LIDAR system such as the controller and the emitter/receiver; a storage medium 510 for storing data or other information; and a processing circuit 512, which communicate with one another via one or more signaling busses or other suitable components, represented by the connection lines in FIG. 5. Programming stored by the storage medium 510, when executed by the processing circuit 512, causes the processing circuit 512 to perform one or more of the various functions and/or process operations described herein.

In at least one example, the processing circuit 512 includes one or more of: a circuit/module 514 for initial processing of combined data from reflected chirps received from the environment and a reference, non-reflected chirp, such as for performing Fast Fourier Transforms; a circuit/module 516 for derivation of spatial coordinates and/or velocity of a reflective surface that provided the reflected chirp and/or deriving range, speed, size, distance, position, and shape, etc.; a circuit/module 518 for derivation of secondary features of a target object such as composition, color and/or surface texture; and a circuit/module 520 for generating a point cloud.

A program stored by the storage medium 510, when executed by the processing circuit 512, may cause the processing circuit 512 to perform one or more of the various functions and/or process operations described herein. As shown in FIG. 5, the storage medium 510 may include one or more of: code 526 for initial processing of combined data, such as for performing Fast Fourier Transforms; code 528 for derivation of spatial coordinates and/or velocity of a reflective surface that provided the reflected chirp and/or deriving range, speed, size, distance, position, and shape, etc.; code 530 for derivation of secondary features of a target object such as composition, color and/or surface texture; and code 532 for generating a point cloud.

In at least some examples, means may be provided for performing the functions illustrated in FIG. 5 and/or other functions illustrated or described herein. For example, the means may include one or more of: means, such as circuit/module 514, for initial processing of combined data, such as for performing Fast Fourier Transforms; means, such as circuit/module 516, for derivation of spatial coordinates and/or velocity of a reflective surface that provided the reflected chirp and/or deriving range, speed, size, distance, position, and shape, etc.; means, such as circuit/module 518, for derivation of secondary features of a target object such as composition, color and/or surface texture; and means, such as circuit/module 520, for generating a point cloud.

### Exemplary Embodiments Pertaining to a Self-Injection Locked GaN Laser

Narrow linewidth coherent blue light may be created using nonlinear optics, e.g. by frequency doubling of 800-900 nm light emitted by stabilized diode of solid state lasers. However, this technique often employs bulky and high-power consuming equipment and may face certain restrictions undesirable for on-chip devices. GaN-based miniature semiconductor lasers are useful for many applications requiring blue coherent light. Unfortunately, GaN lasers do not produce single longitudinal mode coherent light for high-precision applications. This problem may be solved by external cavity diode lasers (ECDL) involving antireflection coated GaN laser chips having single-mode operation and much better coherence characteristics. For instance, an ECDL characterized with 4 nm tuning and 0.8 MHz linewidth measured at 50 ms averaging time has been demonstrated for spectroscopy applications. However, such devices have moving parts and their planar integration is problematic.

Herein, a self-injection locked GaN laser involving a high quality-factor (Q-factor) WGM cavity is described. The self-injection locking results in true single mode operation of the laser. The stabilized laser linewidth is <1 MHz, corresponding to loaded Q values exceeding a billion. Additionally, lasers stabilized using self-injection locking can be tightly integrated.

As noted above, self-injection locking is an efficient technique for locking a laser to an optical ring resonator. The self-injection locking does not depend on the resonator morphology and is efficient for any ring cavity provided there is a significant optical feedback to the laser as well as high quality factor of the cavity. Herein, an exemplary method involves resonant Rayleigh scattering in the WGM resonator occurring due to surface and volumetric inhomogeneities. Some amount of light reflects back into the laser when the frequency of the emitted light coincides with the frequency of a resonator mode, providing an optical feedback, which leads to reduction of laser linewidth. In case of small Rayleigh scattering, an additional mode matched reflector can be utilized that increases coupling between clockwise and counterclockwise modes in the resonator.

In these examples, it is important to use a high-Q resonator to achieve efficient self-injection locking. Most optical materials have higher absorption at shorter wavelength and the Q-factor of the resonators (e.g. WGM resonators) is smaller at shorter wavelengths. For instance, a WGM resonator made from z-cut stoichiometric lithium niobate crystal doped with 1.2% magnesium oxide has intrinsic Q-factor of 7.7×10⁶ at 488 nm, while the Q-factor of a WGM resonator made of a similar material can exceed 108 at telecom wavelength. On the other hand, proper material selection leads to increase of Q-factor and Q-factor of 1.5×10⁸ have been demonstrated in beta barium borate WGM resonators at 370 nm. Previously, a WGM resonator made of a lithium tetraborate crystal with intrinsic quality factor of 2×10⁸ at 490 nm was also fabricated.

Herein, examples are described having high Q-factors exceeding 10⁹ in magnesium fluoride (MgF₂) WGM resonator at an operating wavelength of 446.5 nm, and achieve efficient self-injection locking to the resonator mode.

The self-injection locking method performs well with single longitudinal mode distributed-feedback semiconductor lasers. GaN lasers usually produce a multi-mode spectrum. A wavelength selective external cavity paired with a WGM resonator is used to achieve single mode operation in the case of multi-mode lasers. This configuration can potentially reduce the laser linewidth to sub-Hz but it can be inconvenient for planar integration since it is similar to the standard ECDL structure. Herein, examples are described that provide for selection of the WGM resonator morphology to achieve both self-injection locking and realizing single-mode operation of the self-injection locked laser, which does not operate in the single mode regime if unlocked.

An experimental setup (not shown herein) may be used to demonstrate some of these features. In one example, light emitted from a 446.5 nm GaN Fabry-Pérot (FP) semiconductor laser mounted in a TO can attached to a thermoelectric cooler is collimated and coupled into a MgF₂ WGM resonator, using an anti-reflection coated BK7 glass prism. The laser operating current is 20 mA, which is 4 mA above the threshold current at the measurement temperature (T=22° C.). The laser may be operated at a low injection current value to utilize the relatively narrow emission spectrum of the diode at these low currents, which prevents mode hopping between competing FP modes injection locked to the WGM. The power at the output of the laser may be 4 mW and the power at the output port of the prism is approximately 3 mW. The reduction in power occurs mainly due to backward reflection and attenuation of the light in the resonator. The laser frequency can be pulled by the WGM frequency in a range exceeding 2 GHz. A feedback to the laser current and temperature allows achieving orders of magnitude broader tunability without any efficiency dips.

An exemplary fabricated MgF2 resonator is 2 mm in diameter and 0.1 mm in thickness. The emission of the laser diode is collimated and coupled to the resonator using a 0.53 NA and 1.5 mm focal length lens, so that mode matching is achieved between the laser diode and the resonator. To increase stability, the lens and the laser are mounted on a monolithic platform. The coupling prism is symmetric and is characterized with 55° angle. The prism is anti-reflection coated to have 98% transmission in the vicinity of 450 nm. To reduce or minimize phase fluctuations, the total cavity length is kept as short as possible ˜2 cm. The smaller length also helps in maintaining the FSR of the total cavity comparable to the FSR of the WGM resonator, which prevents mode hopping. Nearly critical coupling of light from the laser to the resonator is achieved by adjusting the gap between the resonator and prism.

A small portion of the original beam is sampled to measure the laser spectrum, using a 200 μm core multimode fiber. To measure the spectrum of the laser diode, one can employ an Ocean Optics spectrometer with a resolution of 0.05 nm at a wavelength range around 450 nm. The laser is first parked at a frequency outside of a selected WGM. In this case, the mode does not impact the laser emission.

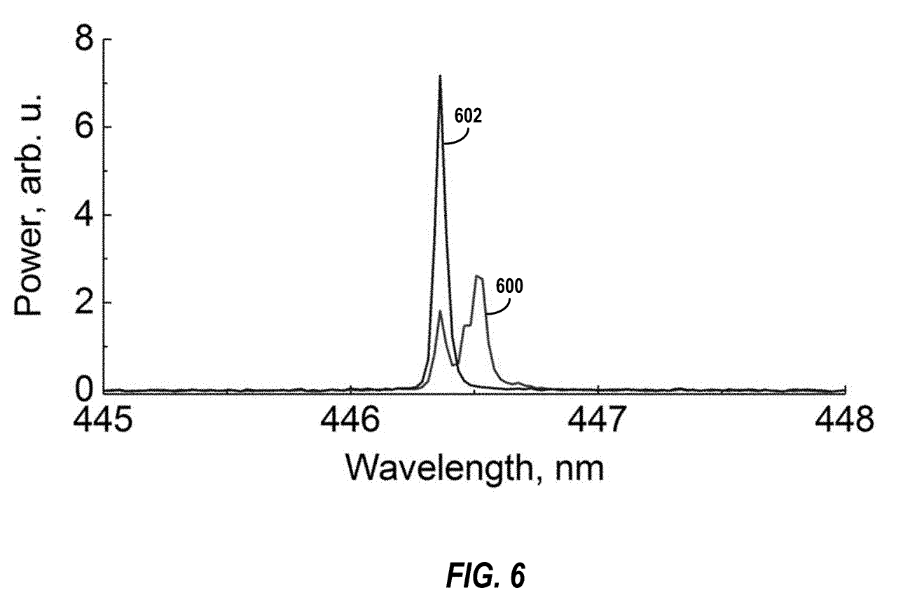

FIG. 6 illustrates the spectrum of the free running laser in curve 600 of a graph that shows wavelength in nm on the horizontal axis and power in arbitrary units on the vertical axis. Two major and a few surrounding peaks of the FP laser diode can be observed. The number of peaks increases with driving current. Thereafter, the current of the laser chip is tuned so that the diode becomes self-injection locked to a mode of the WGM MgF₂ cavity. The resulting spectrum plotted using curve 604 of FIG. 6. That is, FIG. 6 shows a modification of a laser spectrum due to self-injection locking where curve 602 is the spectrum of the self-injection locked laser and curve 600 is the spectrum of the free running laser. The peak power of the self-injection locked laser is approximately 3 mW. The broad spectrum of the FP diode laser collapses into a single mode, due to preferential feedback to the laser chip mode from the resonator with the dominant oscillating condition. Notably, single mode operation is achieved without any additional selection done by a diffraction grating. This observation allows one to simplify the schematic of the laser significantly.

In some examples, light from the output port of the coupling prism is coupled into a multimode fiber (200 μm core), which monitors injection locking using a silicon photo diode (such as a Thorlabs DET 10A with 380 MHz bandwidth). The input current of the laser diode is ramped linearly using a function generator and the response of light coupled into the resonator is monitored. The observed dependence of the photodiode voltage on the laser current is called the LI curve.

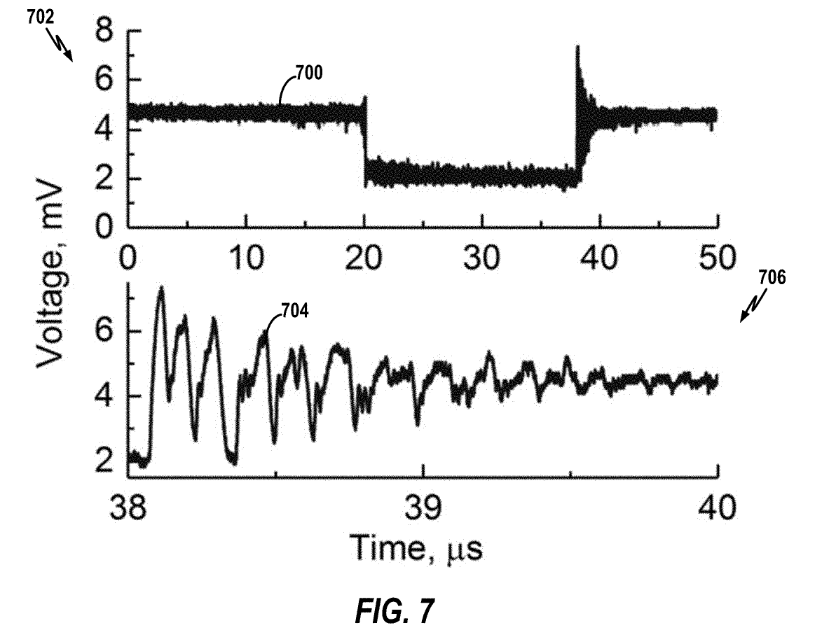

FIG. 7 illustrates the effect of injection locking of the laser diode to a WGM, where the output power (and the photodiode voltage) drops when the laser locks to a WGM. In the exemplary design, a maximum locking range of 0.5 mA is measured. Coupling efficiency into the ring cavity exceeds 60% as seen from the LI curve 700 within a first graph 702 of the figure, in which the horizontal axis shows time in νsecs and the vertical axis shows voltage in mV. To measure the quality factor of the resonator, one can perform a ring down measurement observing a transient process at the LI curve, taking advantage of the fast silicon photodiode. This measurement technique stems from the optical feedback enhanced continuous wave cavity ring down spectroscopy. In this technique, the laser frequency is scanned through the cavity spectrum by changing the laser current. The ring down signal is measured by tuning the laser light off the resonator mode. The light exiting the resonator creates a beat note signal. The tuning off time for the self-injection locking (1 ns) is defined by the intrinsic Q-factor of the diode laser. This is fast enough to observe the ring down signal in this example.

The laser output power is maintained at 4 mW. The laser current is swept fast enough (the frequency sweep speed exceeds 10 GHz s⁻¹). The laser unlocks at much shorter time scale than the ring down time of the loaded resonator mode. The fast scan speed prevents relocking of the laser. The direction of the frequency scanning is selected so that the nonlinear optical frequency shift increases the optical detuning between the mode and the laser light during the unlocking process. The exemplary resonator has a single coupler. As a result, the light exiting the resonator interferes with the light emitted by the laser resulting in time dependent fringes. An oscilloscope may be employed with large digitization to accurately capture the ring down oscillations.

FIG. 7 also illustrates the microsecond level ring down 704, within a second graph 706, in which the horizontal axis shows time in νsecs and the vertical axis shows voltage in mV. The Q-factor can be estimated from the formula Q=πc τ/λ, where c is the speed of light in the vacuum, τ is the ring down time of the LI curve, and λ is the wavelength. Here, one can take into account that τ represents the amplitude ring down time because of the interference effect. This is not exactly true for the laser, since the light exiting the unlocked laser is frequently nearly incoherent if compared with the light escaping the resonator. As the result, in many cases the interference fringes are absent. A regime when the light emitted by the unlocked laser has mostly single mode in its spectrum can be found, such that a beat note is observed. Q-factor for the microsecond level ringdown time is 2×10⁹. This appears to be the highest Q-factor of a monolithic microcavity observed so far in this wavelength range. To verify the Q-factor measurement one can perform another experiment and measure ring down signal of a high-order WGM. This measurement allows significant suppression of the background light coming from the pump laser.

Thus FIG. 7 illustrates dependence of the laser power on the current (LI curve) for a self-injection locked UV laser. (Although UV light might not be ideal for underwater LIDAR applications, self-injection locked UV lasers have their uses as well.) The current is linearly ramped with rate of approximately 30 μA μs⁻¹ represented in units of time. Curve 700 shows that the locking range of the laser corresponds to 0.5 mA in laser current or approximately 2 GHz in laser frequency. Curve 704 shows the ring down signal observed at the moment of unlocking the laser from the resonator mode. The signal thus illustrates amplitude ring down of the cavity mode.

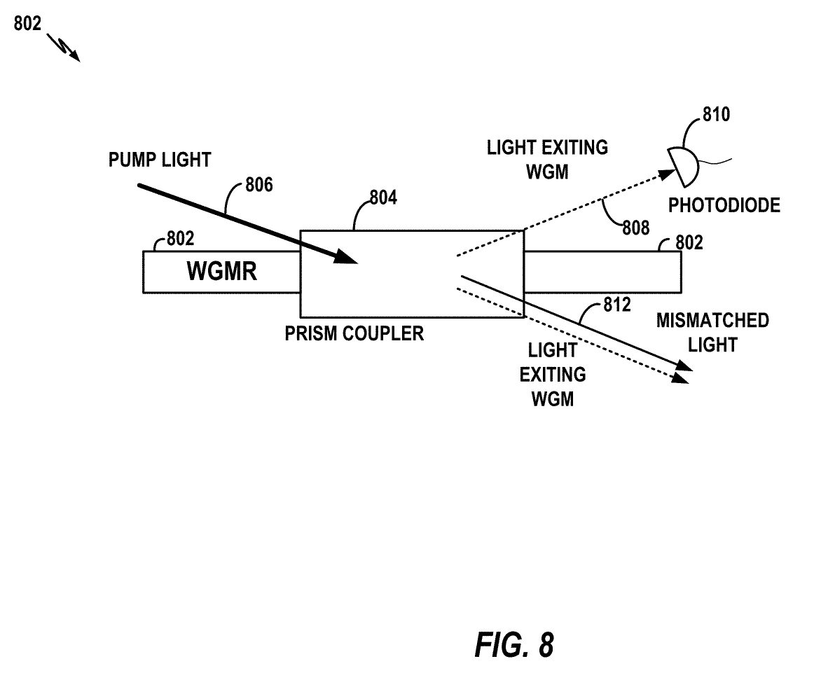

FIG. 8 illustrates that high order WGMs 800 can emit in two directions. In the example of FIG. 8, a WGM resonator 802 is coupled to a prism coupler 804. Pump light 806 entering the WGM resonator 802 via the prism coupler 804 is split in a first output beam 808 that may be applied to a photodiode 810. A second portion of the emitted light is mismatched light 812. That is, the figure shows a top view of the resonator and a coupling prism. Pump light is directed at some angle with respect to the resonator plane. The light exits the mode in two directions defined by the mode geometry. One of the directions is spatially isolated from the pump that did not enter the resonator. Hence, FIG. 8 shows the removal of the mode of mismatched light due to spatial filtering based on the WGM precession effect.

If the WGM is fed with a well-collimated pump beam along one of the directions, the emission in the other direction is not contaminated with the pump that does not couple to the mode. As the result, placing an aperture and a photodiode in the proper position allows observation of true power decay from the resonator mode when the laser is unlocked from the mode. In this manner, the broadband emission of the unlocked laser is filtered out. This technique has a high signal to noise ratio and allows one to conclude that the Q-factor of the high order mode (Q=2πcτ_{power}/λ) exceeds 2×10⁹. Such experiments do not provide direct information about the linewidth of the self-injection locked laser; however, they do allow one to estimate the linewidth to be <1 MHz.

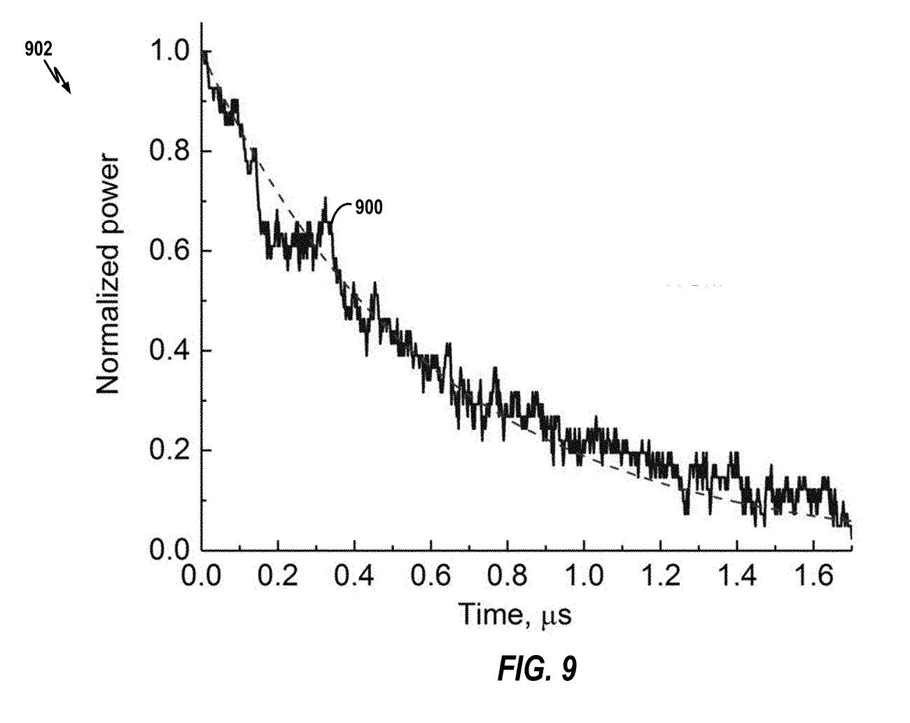

FIG. 9 illustrates normalized power over time and shows a 60% contrast (percentage of total laser power circulating in the resonator), which may be observed in LI curve 900 (which means that 40% of the laser power is either reflected back or attenuated in the resonator mode). In FIG. 9, the horizontal axis shows time in μsecs and the vertical axis shows normalized power. That is, FIG. 9 illustrates that a power ring down signal measured in a high order mode of the resonator. The dashed line 902 represents an exponential fit with time constant of τ_{power}=0.6 μs. The aforementioned feedback happens only in the case of laser linewidth being comparable with the mode bandwidth γ, which is approximately 300 kHz (since Q=v0/γ, where v0 is the carrier frequency v0=6.7×1014 Hz). Therefore, one can conclude that the linewidth of the laser is <1 MHz. A more careful measurement involving, either another laser or an interferometer may be used to find the actual laser linewidth.

The normalized power spectral density of emission of an ideal laser is described by Lorentzian frequency dependence

$$S ( f ) = \frac{Δ v / π}{{f}^{2} + Δ {v}^{2}} \qquad ( 1 )$$

where 2Δv is the laser linewidth and f is the spectral frequency. The resonator mode introduces power filter function expressed in terms of coupling γ_{c} and intrinsic γ₀ decay rates

$$H ( f ) = \frac{{( {γ}_{c} - {γ}_{0} )}^{2} + {f}^{2}}{{( {γ}_{c} + {γ}_{0} )}^{2} + {f}^{2}} \qquad ( 2 )$$

where 2(γ_{c}+γ₀) is full width at the half maximum of the mode. In case of identical coupling and intrinsic decay rates (γ_{c}=γ₀), the resonator absorbs all the light entering the mode. This case corresponds to critical coupling. Equation (2) does not take into consideration backscattering in the resonator, which changes the contrast. However, one can assume that this scattering is relatively small.

The LI curve shown in FIG. 7 represents relative power degradation of the laser light when the laser locks to the mode. The degradation occurs because the laser emission becomes narrowband and starts entering the resonator. Emission of the unlocked laser practically does not enter the mode because the ratio of the mode bandwidth and linewidth of the free running laser is less than 0.1%. The relative power transmitted to a photodiode when the laser is locked is given by convolution of the spectral power density and the filtering function (we assume resonant tuning)

$$\frac{Δ P}{P} ≃ {\int }_{- ∞}^{∞} S ( f ) H ( f ) df = \frac{{( {γ}_{c} - {γ}_{0} )}^{2} + ( {γ}_{c} + {γ}_{0} ) Δ v}{( {γ}_{c} + {γ}_{0} ) ( {γ}_{c} + {γ}_{0} + Δ v )} . \qquad ( 3 )$$

The attenuation of the light with finite linewidth is always less than the attenuation of the light with an infinitely small linewidth. For given contrast of LI curve C=1−ΔP/P<4γ_{c}γ₀/(γ_{c}+γ₀)² the linewidth of the light can be found. For the case of critical coupling that was used in the above-described experiments, γ_{c}=γ₀=γ/4, where γ is the full width at the half maximum of the resonance, the laser linewidth δᵥ is given by

$$Δ v = \frac{1 - C}{2 C} γ . \qquad ( 4 )$$

If the observed contrast approaches unity (100%), the linewidth is much smaller than the bandwidth of the mode. In the instant case C˜0.6, which gives Δv=γ/3. Therefore, the linewidth is approximately 0.1 MHz for γ=300 kHz. Thus, the foregoing discusses demonstration of self-injection locking of a GaN FP semiconductor laser using a high-Q magnesium fluoride WGM resonator. The loaded quality factor of the resonator mode, in this example, exceeds a billion at 446.5 nm, which facilitates ultra-narrow line blue diode lasers suitable for various LIDAR and other applications.

### Additional Exemplary Embodiments

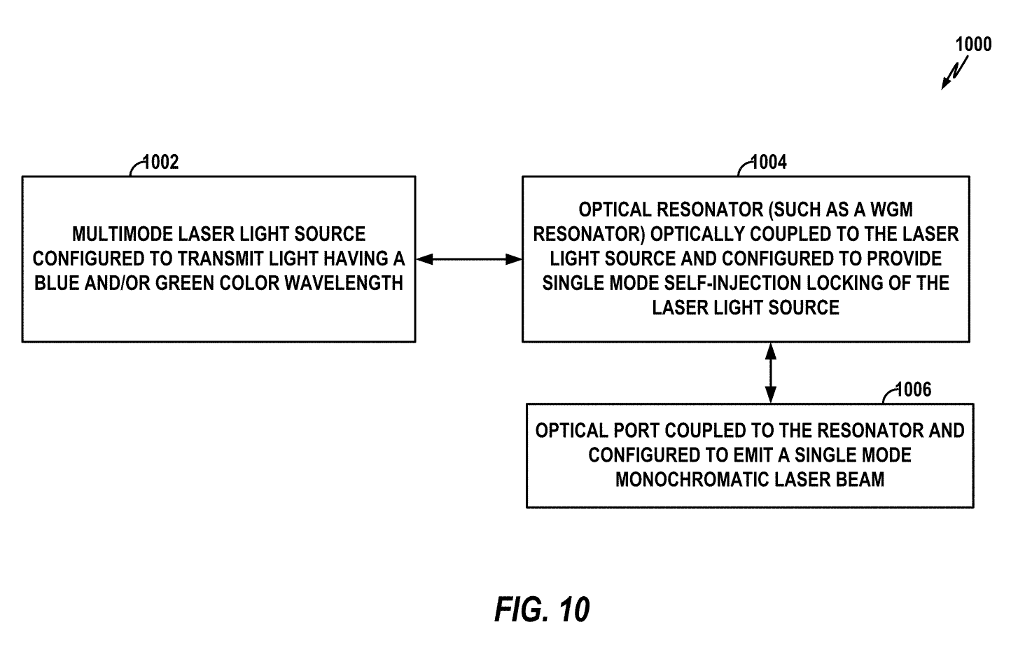

FIG. 10 summarizes features of an exemplary system or apparatus embodiment in accordance with one aspect of the disclosure. System or apparatus 1000 includes a multimode laser light source 1002 configured to transmit light having a blue and/or green color wavelength. The system or apparatus 1000 also includes an optical resonator 1004 (such as a WGM micro-resonator) optically coupled to the laser light source and configured to provide single mode injection locking of the laser light source. The system or apparatus 1000 also includes an optical port 1006 optically coupled to the resonator and configured to emit a single mode monochromatic laser beam. The laser, the resonator, and the optical port may be configured in accordance with the various examples described above.

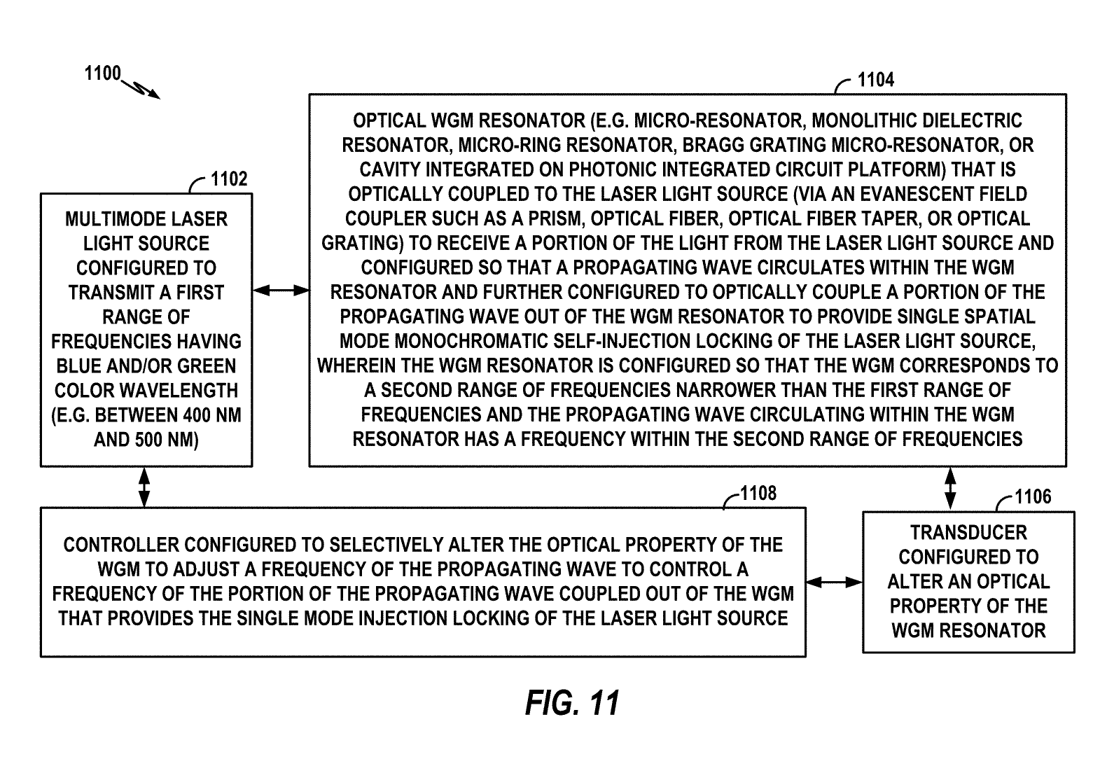

FIG. 11 summarizes additional features of an exemplary system or apparatus embodiment in accordance with an aspect of the disclosure. System or apparatus 1100 includes a multimode laser light source 1102 configured to transmit a first range of frequencies having blue and/or green color wavelength (e.g. between 400 nm and 500 nm). The system or apparatus 1100 also includes a WGM resonator 1104 optically coupled to the laser light source (via an evanescent field coupler such as a prism, optical fiber, optical fiber taper, or optical grating) to receive a portion of the light from the laser light source and configured so that a propagating wave circulates within the WGM resonator and further configured to optically couple a portion of the propagating wave out of the WGM resonator to provide single spatial mode monochromatic injection locking of the laser light source, wherein the WGM resonator is configured so that the WGM corresponds to a second range of frequencies narrower than the first range of frequencies and the propagating wave circulating within the WGM resonator has a frequency within the second range of frequencies. System or apparatus 1100 includes a transducer 1106 configured to alter an optical property of the WGM resonator and a controller 1108 configured to selectively alter the optical property of the WGM to adjust a frequency of the propagating wave to control a frequency of the portion of the propagating wave coupled out of the WGM that provides the single mode injection locking of the laser light source. Although many of the examples herein involve a WGM resonator of the type shown in FIG. 2, in other examples, as indicated in block 1104 of FIG. 11, the optical resonator may be one or more of a micro-resonator, a monolithic dielectric resonator, a micro-ring resonator, a Bragg grating micro-resonator, or a cavity integrated on a photonic integrated circuit platform.

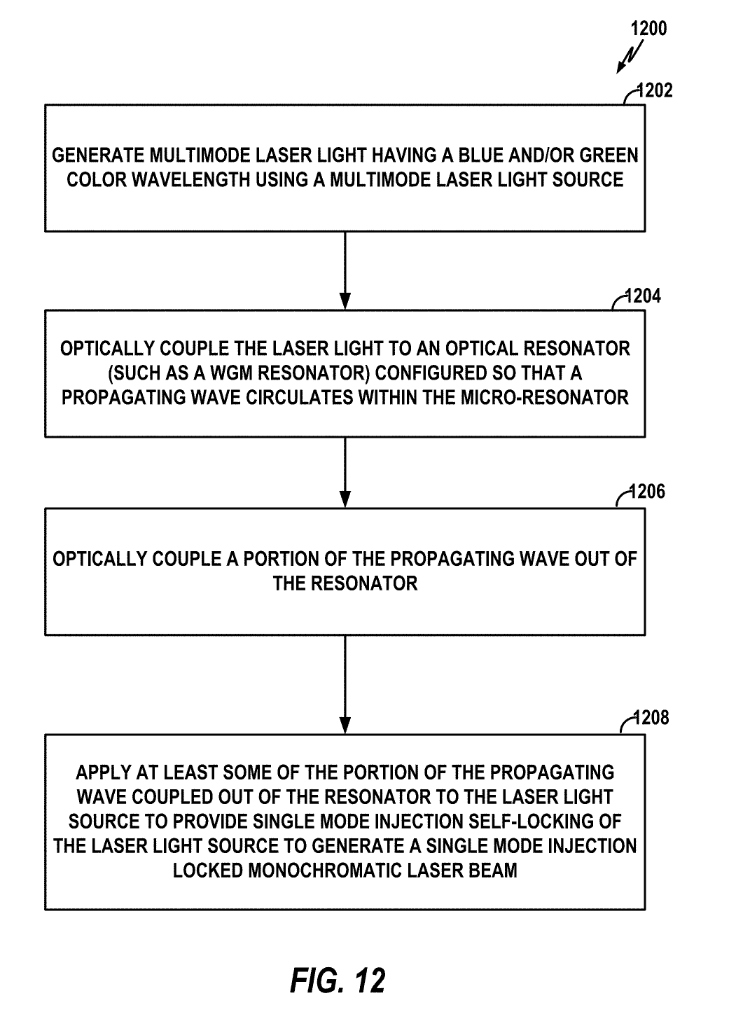

FIG. 12 summarizes features of an exemplary method or procedure embodiment in accordance with one aspect of the disclosure. The method or procedure 1200 may be performed by suitable devices described above such as the device of FIG. 2. Briefly, at block 1202, the device generates multimode laser light having a blue and/or green color wavelength using a multimode laser light source. At block 1204, the device optically couples the laser light to an optical resonator (such as a WGM resonator) configured so that a propagating wave circulates within the resonator. At block 1206, the device optically couples a portion of the propagating wave out of the resonator. At 1208, the device applies at least some of the portion of the propagating wave coupled out of the resonator to the laser light source to provide single mode self-injection locking of the laser light source to generate a single mode injection locked monochromatic laser beam. These operations may be performed in accordance with the various examples described above.

In at least some examples, means may be provided for performing the functions illustrated in FIG. 12 and/or other functions illustrated or described herein. For example, the means may include one or more of: means, such as component 1002, for generating multimode laser light having a blue and/or green color wavelength using a multimode laser light source; means, such as component 1004, for optically coupling the laser light to the optical resonator to cause a propagating wave to circulate within the resonator; means, such as component 1006, for optically coupling a portion of the propagating wave out of the resonator and for applying at least some of the portion of the propagating wave coupled out of the resonator to the laser light source to provide single mode self-injection locking of the laser light source to generate a single mode injection locked monochromatic laser beam.

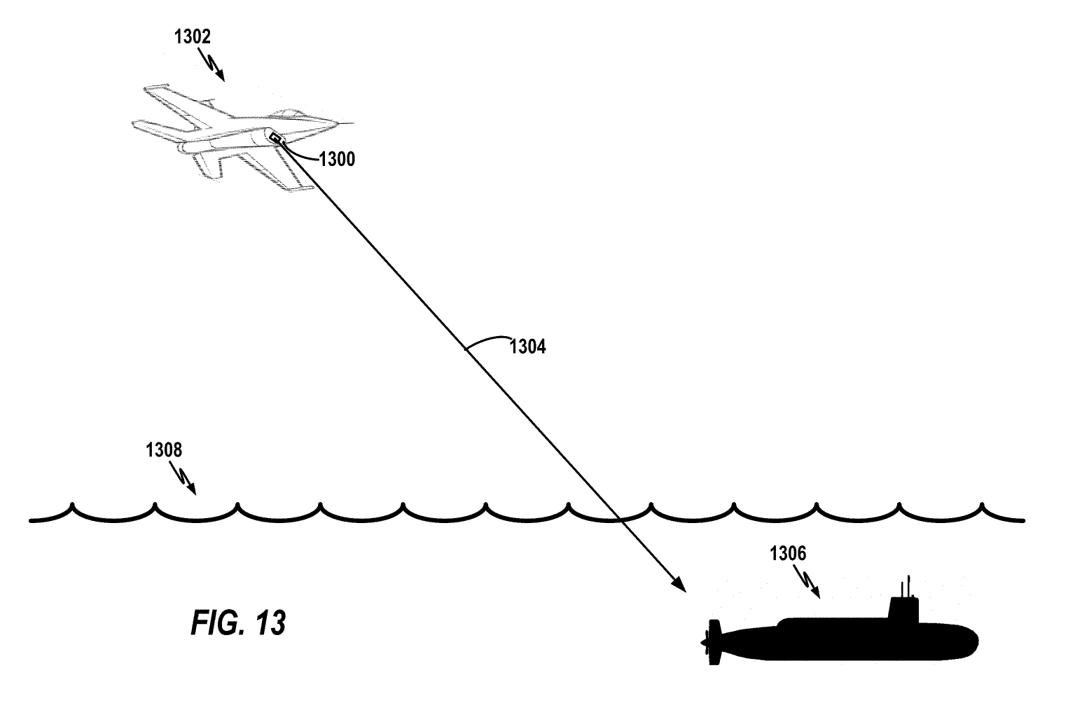

FIG. 13 illustrates LIDAR system or apparatus 1300 mounted within an aircraft 1302 and configured to emit a laser chirp or other laser beam signal 1304 at a blue and/or green wavelength toward a target object 1306, in this example a submarine, which is within a body of water 1308, such as within an ocean or sea. The LIDAR system 1300 may be of the type described above and shown in the various figures.

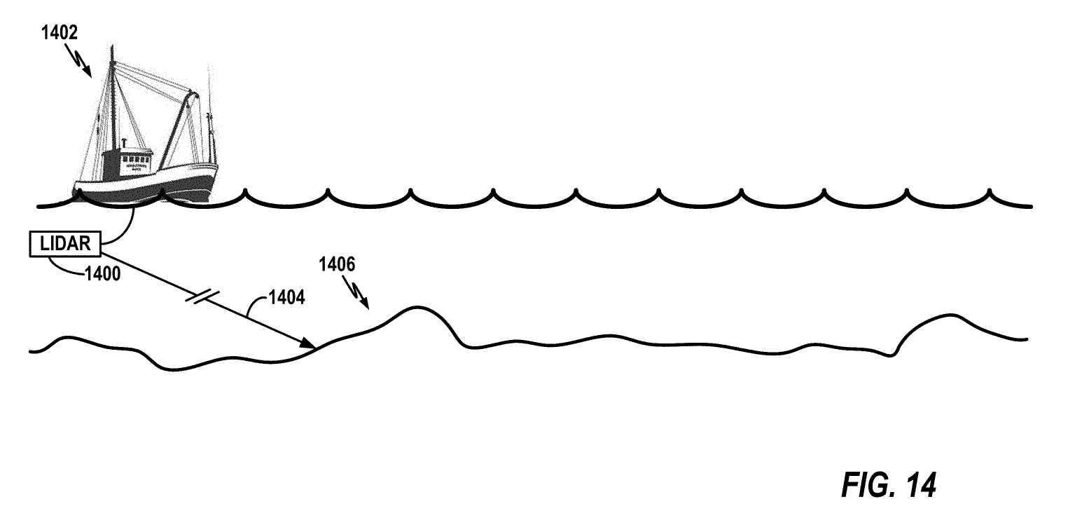

FIG. 14 illustrates a LIDAR system apparatus 1400 hauled beneath the water by a ship 1402, where the LIDAR is again configured to emit a laser chirp or other laser signal 1404 at a blue and/or green wavelength. In this example, the chirp is directed to the seafloor 1406, which is some distance beneath the surface of the ocean, for seafloor mapping. The LIDAR system 1400 may be of the type described above and shown in the various figures.

Note that FIGS. 13 and 14 illustrate just two examples of a wide variety of uses that the LIDAR systems described herein may be put to, where the target object (or objects or surfaces or other features) are underwater. The LIDAR system is also useful for scanning objects that are not within the water and, in general, may be useful wherever a blue and/or green wavelength laser beam is advantageous. Thus, although FIGS. 13-14 show LIDAR used for underwater applications, it should be appreciated that the LIDAR has utility in numerous other non-water-based applications.

Note that one or more of the components, steps, features, and/or functions illustrated in FIGS. 1, 2, 3, 4, 5, 6, 7, 8, 9, 10, 11, 12, 13 and/or 14 may be rearranged and/or combined into a single component, step, feature or function or embodied in several components, steps, or functions. Additional elements, components, steps, and/or functions may also be added without departing from the invention.

The word “exemplary” is used herein to mean “serving as an example, instance, or illustration.” Any implementation or aspect described herein as “exemplary” is not necessarily to be construed as preferred or advantageous over other aspects of the disclosure. Likewise, an aspect is an implementation or example. Reference in the specification to “an aspect,” “one aspect,” “some aspects,” “various aspects,” or “other aspects” means that a particular feature, structure, or characteristic described in connection with the aspects is included in at least some aspects, but not necessarily all aspects, of the present techniques. The various appearances of “an aspect,” “one aspect,” or “some aspects” are not necessarily all referring to the same aspects. Elements or aspects from an aspect can be combined with elements or aspects of another aspect.

The term “coupled” may mean that two or more elements are in direct physical or electrical contact. However, “coupled” may also mean that two or more elements are not in direct contact with each other, but yet still co-operate or interact with each other.

Not all components, features, structures, characteristics, etc. described and illustrated herein need be included in a particular aspect or aspects. If the specification states a component, feature, structure, or characteristic “may,” “might,” “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although some aspects have been described in reference to particular implementations, other implementations are possible. Additionally, the arrangement and/or order of elements or other features illustrated in the drawings and/or described herein need not be arranged in the particular way illustrated and described. Many other arrangements are possible according to some aspects.

Also, it is noted that the aspects of the present disclosure may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Those of skill in the art would further appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An apparatus, comprising:
a multimode laser light source configured to transmit light having a blue and/or green color wavelength;
an optical resonator optically coupled to the laser light source and configured to provide single mode self-injection locking of the laser light source; and
an optical port coupled to the resonator and configured to emit a single mode monochromatic laser beam.

2. The apparatus, of claim 1, wherein the resonator is a whispering gallery mode (WGM) resonator configured so a portion of the light from the light source forms a propagating wave that circulates within the WGM resonator and further configured to optically couple a portion of the propagating wave out of the WGM resonator to provide single spatial mode monochromatic self-injection locking of the laser light source.

3. The apparatus of claim 2,
wherein the multimode laser light source is configured to transmit a first range of frequencies having the blue and/or green color wavelength;
wherein the WGM resonator is configured so the WGM resonator corresponds to a second range of frequencies that is narrower than the first range of frequencies; and
wherein the propagating wave circulating within the WGM resonator has a frequency within the second range of frequencies.

4. The apparatus of claim 2,
wherein the propagating wave circulating within the WGM resonator includes a first propagating wave that circulates in a first direction and a second propagating wave that circulates in a second direction, opposite the first direction, and
wherein the portion of the propagating wave that is optically coupled out of the WGM resonator is a portion of the second propagating wave.

5. The apparatus of claim 4,
wherein the first propagating wave is a clockwise propagating wave and the second propagating wave is a counterclockwise propagating wave.

6. The apparatus of claim 2, further comprising:
a transducer coupled to the resonator and configured to alter an optical property of the resonator; and
a controller operationally coupled to the transducer and configured to selectively alter the optical property of the resonator to adjust a frequency of the propagating wave to control a frequency of the portion of the propagating wave coupled out of the resonator that provides the single mode self-injection locking of the laser light source.

7. The apparatus of claim 1, wherein the multimode laser light source is configured to transmit light having a wavelength between 400 nm and 500 nm.

8. The apparatus of claim 1, wherein the multimode laser light source is configured to transmit light having a wavelength at about 418 nm or at about 480 nm.

9. The apparatus of claim 1, wherein the multimode laser light source has a linewidth of 1 MHz, 10 kHz, or 100 Hz.

10. The apparatus of claim 1, further comprising:
a transmit component configured to direct a portion of the laser beam to a remote object;
a receive component configured to receive a portion of the laser beam reflected from the remote object; and
a processing component configured to detect a characteristic of the remote object.

11. The apparatus of claim 10, wherein the transmit component is configured to direct the portion of the laser beam through water, and wherein the characteristic of the remote object includes one or more of range, speed, velocity, size, distance, position, shape, composition, color, and surface texture.

12. The apparatus of claim 10, wherein the portion of the laser beam directed to the remote object is configured as an optical chirp.

13. The apparatus of claim 11, wherein the apparatus is a Light Detection and Ranging (LIDAR) device.

14. The apparatus of claim 1, further comprising a modulation component configured to modulate the laser beam to communicate information to a remote device.

15. The apparatus of claim 1, wherein the optical resonator is one or more of a micro-resonator, a monolithic dielectric resonator, a micro-ring resonator, a Bragg grating micro-resonator, or a cavity integrated on a photonic integrated circuit platform.

16. The apparatus of claim 1, wherein the optical resonator is optically coupled to the laser light source using an evanescent field coupler comprising a prism, optical fiber, optical fiber taper, or optical grating.

17. A method comprising:
generating multimode laser light having a blue and/or green color wavelength using a multimode laser light source;
optically coupling the laser light to an optical resonator configured so a propagating wave circulates within the resonator;
optically coupling a portion of the propagating wave out of the resonator; and
applying at least some of the portion of the propagating wave coupled out of the resonator to the laser light source to provide single mode self-injection locking of the laser light source to generate a monochromatic single mode injection locked laser beam.

18. The method of claim 17,
wherein the multimode laser light is generated by the multimode laser light source at a first range of frequencies having the blue and/or green color wavelength; and
wherein the propagating wave has a frequency within a second range of frequencies that is narrower than the first range of frequencies.

19. The method of claim 17, wherein the resonator comprises a whispering gallery mode (WGM) resonator, and
wherein the propagating wave circulating within the WGM resonator includes a first propagating wave that circulates in a first direction and a second propagating wave that circulates in a second direction, opposite the first direction, and
wherein the portion of the propagating wave that is optically coupled out of the WGM resonator is a portion of the second propagating wave.

20. The method of claim 17, wherein the multimode laser light source is transmitted at a wavelength between 400 nm and 500 nm.

21. The method of claim 17, wherein the monochromatic laser beam is controllably chirped via a signal applied to the resonator.

22. An apparatus comprising:
an optical resonator;
means for generating multimode laser light having a blue and/or green color wavelength using a multimode laser light source;
means for optically coupling the laser light to the optical resonator to cause a propagating wave to circulate within the resonator; and
means for optically coupling a portion of the propagating wave out of the resonator and for applying at least some of the portion of the propagating wave coupled out of the resonator to the laser light source to provide single mode self-injection locking of the laser light source to generate a single mode injection locked monochromatic laser beam.

23. The apparatus of claim 19, wherein the optical resonator is a whispering gallery mode (WGM) resonator.
